(19) United States
(12) Patent Application Publication
(10) Pub. No.: US 2026/0137011 A1
(43) Pub. Date: May 14, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsing-Yu LIU, Taichung City (TW); Chih-Sheng LIN, Taichung City (TW); Chih-Yuan SHIH, Taichung City (TW)

(21) Appl. No.: 19/004,815

(22) Filed: Dec. 30, 2024

(30) Foreign Application Priority Data
Nov. 8, 2024 (TW) 113143013

(51) Int. Cl. H01L 23/498; H01L 21/48; H01L 21/683; H01L 23/00; H01L 23/367; H01L 25/065

(52) U.S. Cl. CPC H10W 90/401; H10W 70/05; H10W 70/095; H10W 70/65; H10W 70/685; H10W 90/00; H10P 72/74; H10W 40/226; H10W 90/724

(57) ABSTRACT

An electronic package and a manufacturing method thereof are provided. A cladding layer in which at least one electronic element is embedded is provided. A wiring structure and a circuit structure are sequentially formed on the cladding layer. A disconnected portion is formed in the circuit structure to disperse the stress in the wiring structure and the circuit structure, thereby preventing the problem of cracking from occurring to the wiring structure or the circuit structure.

### CROSS-REFERENCE TO RELATED APPLICATIONS

The present application is based upon and claims the right of priority to TW Patent Application No. 113143013, filed Nov. 8, 2024, the disclosure of which is hereby incorporated by reference herein in its entirety for all purposes

### BACKGROUND

### 1. Technical Field

The present disclosure relates to a semiconductor packaging technology, and more particularly, to an electronic package that can improve reliability and a manufacturing method thereof.

### 2. Description of Related Art

In order to ensure the continued miniaturization and multi-functionality of electronic products and communication equipment, semiconductor packages need to develop towards miniaturization in order to facilitate the connection of multiple pins. For example, in advanced packaging process, commonly used packaging types include flip-chip packaging processes, fan-out wiring and embedded element processes, etc.

FIG. 1A to FIG. 1C are schematic cross-sectional views illustrating a manufacturing method of a conventional semiconductor package 1.

As shown in FIG. 1A, a plurality of semiconductor chips 12 are placed on a carrier 9, and then the semiconductor chips 12 are covered with an encapsulant 13.

As shown in FIG. 1B, a build-up structure 15 is formed on the encapsulant 13, and a plurality of solder balls 16 are formed on the build-up structure 15, wherein the build-up structure 15 includes a dielectric layer 150 formed on the encapsulant 13, a circuit layer 151 formed on the dielectric layer 150, and a plurality of conductive blind holes 152 formed in the dielectric layer 150, and the conductive blind holes 152 are electrically connected to the circuit layer 151 and the semiconductor chips 12.

As shown in FIG. 1C, the carrier 9 is removed, and then a singulation process is performed along a cutting path S shown in FIG. 1B.

However, in the manufacturing method of the conventional semiconductor package 1, the semiconductor chips 12 are first embedded in the encapsulant 13, and then the build-up structure 15 is made. Therefore, no underfill is used as a stress buffer mechanism between the build-up structure 15 and the semiconductor chips 12. Accordingly, in subsequent processes, the build-up structure 15 is prone to stress concentration problems to cause the build-up structure 15 to crack, such as cracks K as shown in FIG. 1C, thereby causing damage to the circuit layer 151.

Therefore, how to overcome the above-mentioned drawbacks of the prior art has become an urgent issue to be solved.

### SUMMARY

In view of the various deficiencies of the prior art, the present disclosure provides an electronic package, which comprises: a cladding layer; at least one electronic element embedded in the cladding layer; a wiring structure formed on the cladding layer and including an insulating layer formed on the cladding layer, a wiring layer formed on the insulating layer, and a plurality of first conductive blind vias formed in the insulating layer, wherein the plurality of first conductive blind vias are electrically connected to the wiring layer and the electronic element; and a circuit structure formed on the wiring structure and including at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the circuit layer is formed with a disconnected portion corresponding to a position of the electronic element.

The present disclosure also provides a method of manufacturing an electronic package, the method comprises: forming a cladding layer on at least one electronic element to cover the electronic element; forming a wiring structure on the cladding layer, wherein the wiring structure includes an insulating layer formed on the cladding layer, a wiring layer formed on the insulating layer, and a plurality of first conductive blind vias formed in the insulating layer, wherein the plurality of first conductive blind vias are electrically connected to the wiring layer and the electronic element; and forming a circuit structure on the wiring structure, wherein the circuit structure includes at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the circuit layer is formed with a disconnected portion corresponding to a position of the electronic element.

In the aforementioned electronic package and method, the wiring structure and the circuit structure are of a redistribution layer specification.

In the aforementioned electronic package and method, each of the first conductive blind vias and the disconnected portion are misaligned from each other.

In the aforementioned electronic package and method, the circuit structure includes a plurality of the circuit layers. Further, a plurality of the disconnected portions are arranged on different layers of the plurality of circuit layers.

In the aforementioned electronic package and method, the disconnected portion is located on the circuit layer adjacent to the insulating layer.

In the aforementioned electronic package and method, the disconnected portion is located within a vertical projection area of the first conductive blind via.

In the aforementioned electronic package and method, the disconnected portion is located within a vertical projection area of the electronic element.

In the aforementioned electronic package and method, the single circuit layer has a plurality of the disconnected portions.

As can be seen from the above, in the electronic package and the manufacturing method thereof of the present disclosure, the circuit layer located on the dielectric layer is formed with a disconnected portion to disperse the stress in the wiring structure and circuit structure. Therefore, compared with the prior art, the electronic package can prevent the problem of stress concentration from occurring to the wiring structure and the circuit structure, and prevent the problem of cracking from occurring to the wiring structure or circuit structure. Therefore, damage to the wiring layer or circuit layer can be avoided, so that the product yield and product reliability can be improved.

### BRIEF DESCRIPTION OF THE DRAWINGS

FIG. 1A to FIG. 1C are schematic cross-sectional views illustrating a manufacturing method of a conventional semiconductor package.

FIG. 2A to FIG. 2D are schematic cross-sectional views illustrating a manufacturing method of an electronic package according to the present disclosure.

FIG. 2E is a schematic cross-sectional view illustrating the subsequent process of FIG. 2D.

FIG. 3 is a partial cross-sectional schematic view of another embodiment of FIG. 2D.

FIG. 4A, FIG. 4B and FIG. 4C are partial cross-sectional schematic views of other different embodiments of FIG. 2D.

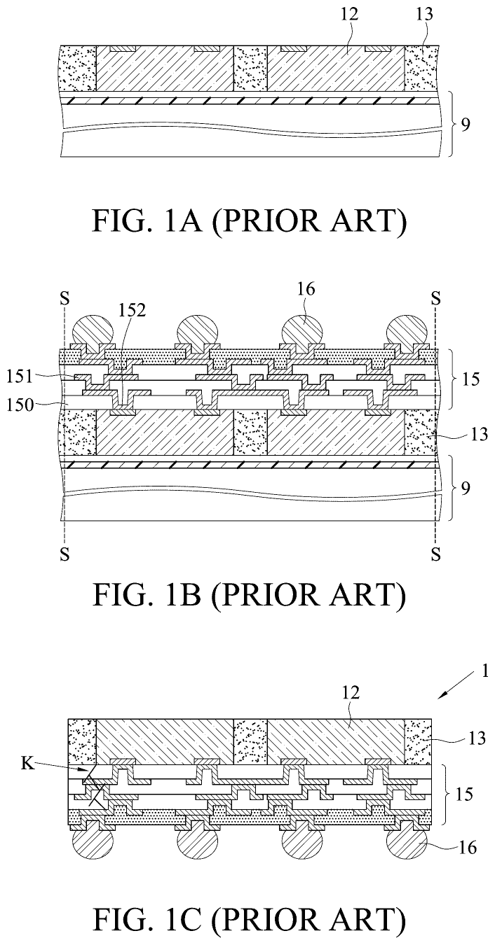

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

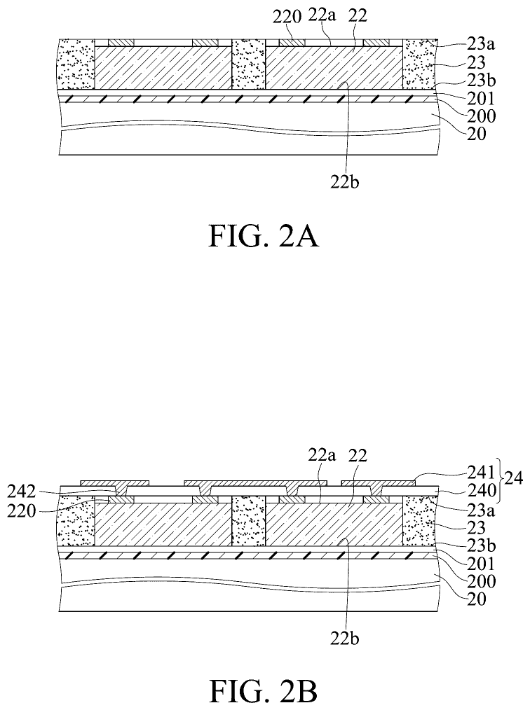

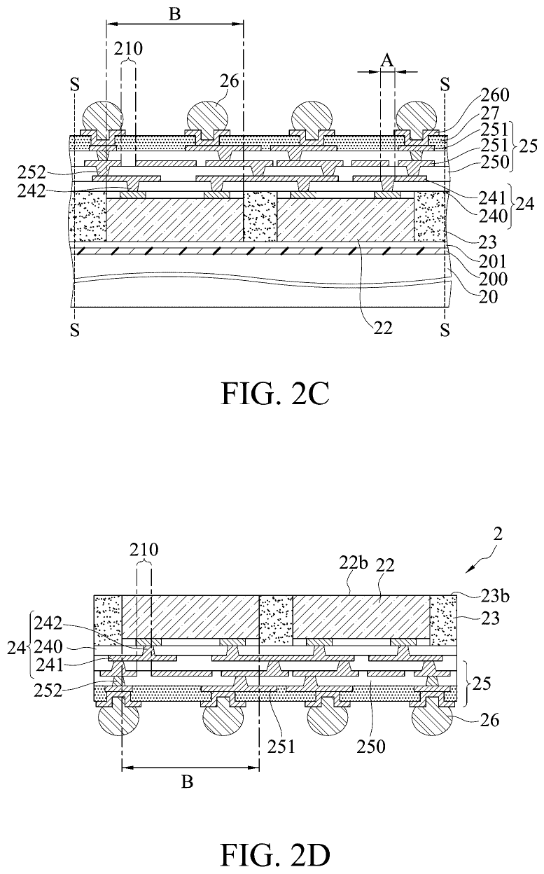

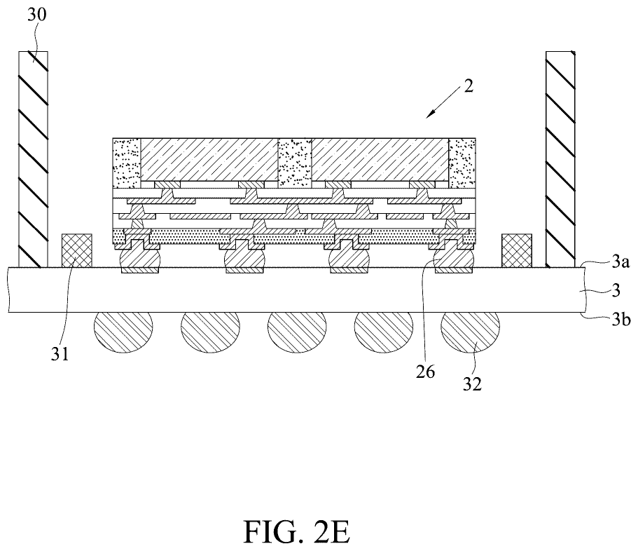

FIG. 2A to FIG. 2D are schematic cross-sectional views illustrating a manufacturing method of an electronic package 2 according to the present disclosure.

As shown in FIG. 2A, at least one electronic element 22 is disposed on a carrier board 20 (the figure of this embodiment shows two electronic elements 22), and then a cladding layer 23 having a first surface 23a and a second surface 23b opposite to the first surface 23a is formed on the carrier board 20 to cover the electronic elements 22, so that the electronic elements 22 are embedded in the cladding layer 23.

A release layer 200 and a bonding layer 201 can be formed sequentially on the carrier board 20, so that the second surface 23b of the cladding layer 23 and the electronic elements 22 are bonded to the bonding layer 201.

In one embodiment, the release layer 200 is a thermal release tape, a photosensitive release film, or a mechanical release structure, and the bonding layer 201 is made of adhesive material.

The cladding layer 23 is made of insulating material, such as dry film, epoxy encapsulating colloid, or epoxy molding compound.

In one embodiment, the cladding layer 23 may be formed on the carrier board 20 by liquid compound, injection, lamination, or compression molding.

Each of the electronic elements 22 is an active element, a passive element, or a combination of the active element and the passive element, wherein the active element is a semiconductor chip, and the passive element is a resistor, a capacitor, or an inductor.

In one embodiment, each of the electronic elements 22 is a semiconductor chip having an active surface 22a and a non-active surface 22b opposite to the active surface 22a, wherein the active surface 22a has a plurality of electrode pads to be bonded to a plurality of conductive bumps 220, and the non-active surface 22b of each of the electronic elements 22 is bonded to the bonding layer 201, so that the plurality of conductive bumps 220 are exposed from the first surface 23a of the cladding layer 23.

As shown in FIG. 2B, a wiring structure 24 is formed on the first surface 23a of the cladding layer 23, and the wiring structure 24 includes an insulating layer 240 formed on the cladding layer 23, a wiring layer 241 formed on the insulating layer 240, and a plurality of first conductive blind vias 242 formed in the insulating layer 240, so that the plurality of first conductive blind vias 242 are electrically connected to the wiring layer 241 and the conductive bumps 220 of each of the electronic elements 22.

In one embodiment, the wiring structure 24 is of a redistribution layer (RDL) specification.

Furthermore, the material for forming the wiring layer 241 and each of the first conductive blind vias 242 is copper, and the material for forming the insulating layer 240 is dielectric material such as polybenzoxazole (PBO), polyimide (PI), prepreg (PP), or the like.

As shown in FIG. 2C, a circuit structure 25 is formed on the wiring structure 24, wherein the circuit structure 25 includes at least one dielectric layer 250 formed on the insulating layer 240, at least one circuit layer 251 formed on the dielectric layer 250, and a plurality of second conductive blind vias 252 formed in the dielectric layer 250, and the plurality of second conductive blind vias 252 are electrically connected to the circuit layer 251 and the wiring layer 241.

In one embodiment, the circuit structure 25 is of RDL specification, and the material for forming the circuit layer 251 and each of the second conductive blind vias 252 is copper. In the illustration of this embodiment, the circuit structure 25 includes a plurality of the dielectric layers 250, and the material for forming each of the dielectric layers 250 is dielectric material such as polybenzoxazole (PBO), polyimide (PI), prepreg (PP), or the like. In addition, the outermost side of the circuit structure 25 can use solder-resist material such as solder mask, graphite, or the like as an insulating protective layer 27, and portions of the outermost circuit layer 251 are exposed from the insulating protective layer 27 to be bonded to a plurality of conductive elements 26. For example, each of the conductive elements 26 is a solder bump or metal bump containing solder material of a controlled-collapse chip connection (C4) specification, and an under-bump metallurgy (UBM) layer 260 can be formed on the circuit layer 251 before the conductive elements 26 are formed so as to facilitate bonding with the conductive elements 26.

In addition, the dielectric layer 250 can be made of the same material as the insulating layer 240, and the circuit layer 251 and each of the second conductive blind vias 252 may be made of the same material as the wiring layer 241 and each of the first conductive blind vias 242.

Furthermore, the circuit layer 251 is formed with disconnected portions 210 like notches corresponding to the position of each of the electronic elements 22. In one embodiment, each of the disconnected portions 210 is located within a vertical projection area B of each of the electronic elements 22, preferably at the edge of the vertical projection area B of each of the electronic elements 22.

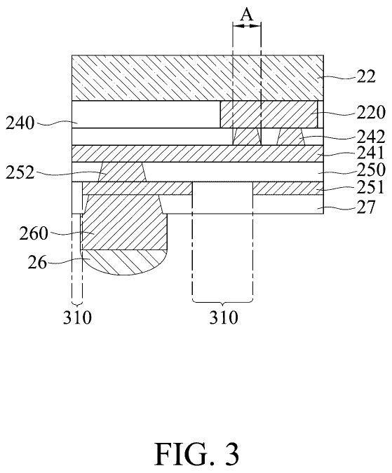

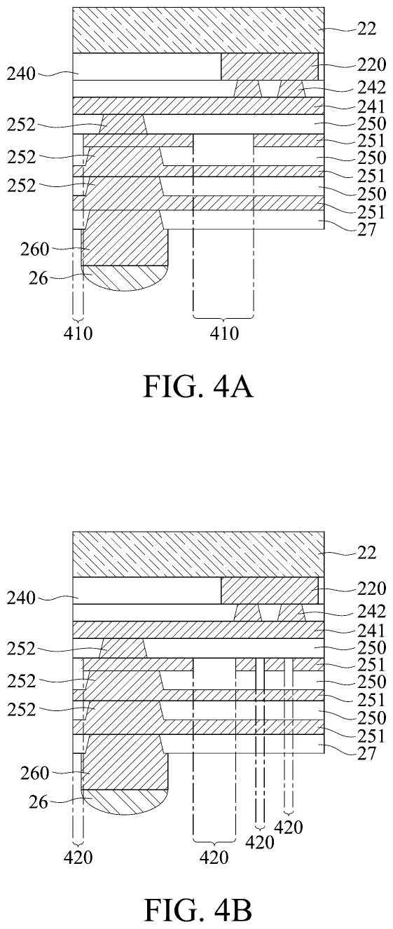

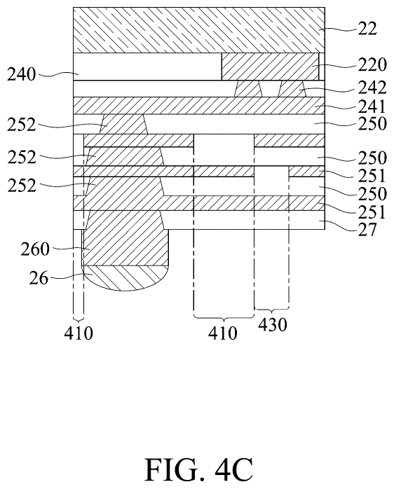

In one embodiment, the number of layers of the circuit layer 251 can be designed according to requirements, such as two layers as shown in FIG. 2C, one layer as shown in FIG. 3, or three layers as shown in FIG. 4A, so that the position of the disconnected portion 210, 310, 410 can be configured in any circuit layer 251 as required. For example, the disconnected portion 210, 310, and 410 shown in FIG. 2C, FIG. 3, or FIG. 4A is located near the circuit layer 251 of the insulating layer 240. That is, the disconnected portion 210, 310, 410 is adjacent to the circuit layer 251 of the insulating layer 240 and should be as close as possible to the electronic element 22, wherein the closer the circuit layer 251 is to the electronic element 22, the greater the stress on the circuit layer 251.

In one embodiment, the disconnected portion 210, 310, 410 is not aligned with the first conductive blind via 242, so the disconnected portion 210, 310, 410 and the first conductive blind via 242 are misaligned with each other. In another embodiment, the disconnected portion 210, 310, 410 is located within a vertical projection area A of each of the first conductive blind vias 242.

As shown in FIG. 2D, the carrier board 20, the release layer 200 and the bonding layer 201 are removed, so that the non-active surface 22b of the electronic element 22 is exposed from the second surface 23b of the cladding layer 23. Thereafter, a singulation process is performed along a cutting path S as shown in FIG. 2C.

In addition, as shown in FIG. 2E, in the subsequent process, the electronic package 2 can be bonded to an electronic device 3 such as a circuit board via the conductive elements 26, wherein the electronic package 2, at least one heat sink 30 and at least one passive element 31 can be disposed on an upper side 3a of the electronic device 3, and a plurality of solder balls 32 can be disposed on a lower side 3b of the electronic device 3.

Therefore, in the manufacturing method of the present disclosure, the circuit layer 251 located on the dielectric layer 250 is formed with the disconnected portions 210, 310, 410 to disperse the stress in the wiring structure 24 and the circuit structure 25. Therefore, compared with the prior art, the electronic package 2 can effectively prevent the stress concentration problem from occurring to the wiring structure 24 and the circuit structure 25 so as to prevent the wiring structure 24 or the circuit structure 25 from cracking. Therefore, damage to the wiring layer 241 or circuit layer 251 can be avoided, so that the product yield and product reliability can be improved.

Furthermore, in other embodiments, according to stress requirements, the circuit layer 251 located on a dielectric layer 250 can be broken into a plurality of segments to form a plurality of disconnected portions 420, such as a mesh shown in FIG. 4B. Therefore, the electronic package 2 can be even more capable of preventing the problem of stress concentration from occurring to the wiring structure 24 and the circuit structure 25 so as to prevent the problem of cracking from occurring to the wiring structure 24 or the circuit structure 25.

It should be understood that the number of disconnected portions can be configured on the circuit layer 251 of the circuit structure 25 according to needs. As shown in FIG. 4A and FIG. 4B, a plurality of disconnected portions 410 and 420 can be formed in a single circuit layer 251, or as shown in FIG. 4C, the disconnected portions 410 and 430 can be formed in circuit layers 251 of different layers.

The present disclosure further provides an electronic package 2, which comprises: a cladding layer 23, at least one electronic element 22 embedded in the cladding layer 23, a wiring structure 24 disposed on the cladding layer 23, and a circuit structure 25 disposed on the wiring structure 24, wherein the circuit structure 25 is formed with disconnected portions 210, 310, 410, 420, 430.

The wiring structure 24 includes an insulating layer 240 formed on the cladding layer 23, a wiring layer 241 formed on the insulating layer 240, and a plurality of first conductive blind vias 242 formed in the insulating layer 240, so that the plurality of first conductive blind vias 242 are electrically connected to the wiring layer 241 and the electronic element 22.

The circuit structure 25 includes at least one dielectric layer 250 formed on the insulating layer 240, at least one circuit layer 251 formed on the dielectric layer 250, and a plurality of second conductive blind vias 252 formed in the dielectric layer 250, wherein the plurality of second conductive blind vias 252 are electrically connected to the circuit layer 251 and the wiring layer 241, wherein the circuit structure 25 is formed with the disconnected portions 210, 310, 410, 420, 430.

In one embodiment, the wiring structure 24 and the circuit structure 25 are of a redistribution layer (RDL) specification.

In one embodiment, the first conductive blind vias 242 and the disconnected portions 210, 310, 410, 420, 430 are misaligned from each other.

In one embodiment, the circuit structure 25 includes a plurality of circuit layers 251. For example, the disconnected portions 210, 310, 410, 420, and 430 are disposed on different layers of the circuit layers 251.

In one embodiment, the disconnected portion 210, 310, 410, 420, 430 is located within a vertical projection area A of the first conductive blind via 242.

In one embodiment, the disconnected portion 210, 310, 410, 420, 430 is located within a vertical projection area B of the electronic element 22.

In one embodiment, the disconnected portion 210, 310, 410, 420, 430 is located in the circuit layer 251 adjacent to the insulating layer 240.

In one embodiment, a plurality of disconnected portions 420 are formed on a single circuit layer 251.

To sum up, in the electronic package and the manufacturing method thereof of the present disclosure, the circuit layer located on the dielectric layer is formed with a disconnected portion to disperse the stress in the wiring structure and circuit structure. Therefore, the electronic package can effectively prevent the problem of stress concentration from occurring to the wiring structure and the circuit structure, and prevent the problem of cracking from occurring to the wiring structure or circuit structure.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a cladding layer;
at least one electronic element embedded in the cladding layer;
a wiring structure formed on the cladding layer and including an insulating layer formed on the cladding layer, a wiring layer formed on the insulating layer, and a plurality of first conductive blind vias formed in the insulating layer, wherein the plurality of first conductive blind vias are electrically connected to the wiring layer and the electronic element; and
a circuit structure formed on the wiring structure and including at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the circuit layer is formed with a disconnected portion corresponding to a position of the electronic element.

2. The electronic package of claim 1, wherein the wiring structure and the circuit structure are of a redistribution layer specification.

3. The electronic package of claim 1, wherein each of the first conductive blind vias and the disconnected portion are misaligned from each other.

4. The electronic package of claim 1, wherein the circuit structure includes a plurality of the circuit layers.

5. The electronic package of claim 4, wherein a plurality of the disconnected portions are arranged on different layers of the plurality of circuit layers.

6. The electronic package of claim 1, wherein the disconnected portion is located on the circuit layer adjacent to the insulating layer.

7. The electronic package of claim 1, wherein the disconnected portion is located within a vertical projection area of the first conductive blind via.

8. The electronic package of claim 1, wherein the disconnected portion is located within a vertical projection area of the electronic element.

9. The electronic package of claim 1, wherein the single circuit layer has a plurality of the disconnected portions.

10. A method of manufacturing an electronic package, comprising:
forming a cladding layer on at least one electronic element to cover the electronic element;
forming a wiring structure on the cladding layer, wherein the wiring structure includes an insulating layer formed on the cladding layer, a wiring layer formed on the insulating layer, and a plurality of first conductive blind vias formed in the insulating layer, wherein the plurality of first conductive blind vias are electrically connected to the wiring layer and the electronic element; and
forming a circuit structure on the wiring structure, wherein the circuit structure includes at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the circuit layer is formed with a disconnected portion corresponding to a position of the electronic element.

11. The method of claim 10, wherein the wiring structure and the circuit structure are of a redistribution layer specification.

12. The method of claim 10, wherein each of the first conductive blind vias and the disconnected portion are misaligned from each other.

13. The method of claim 10, wherein the circuit structure includes a plurality of the circuit layers.

14. The method of claim 13, wherein a plurality of the disconnected portions are arranged on different layers of the plurality of circuit layers.

15. The method of claim 10, wherein the disconnected portion is located on the circuit layer adjacent to the insulating layer.

16. The method of claim 10, wherein the disconnected portion is located within a vertical projection area of the first conductive blind via.

17. The method of claim 10, wherein the disconnected portion is located within a vertical projection area of the electronic element.

18. The method of claim 10, wherein the single circuit layer has a plurality of the disconnected portions.
